(19) United States
(12) Patent Application Publication
(10) Pub. No.: US 2026/0123125 A1
(43) Pub. Date: Apr. 30, 2026

(54) LIGHT EMITTING DEVICE AND MODULE HAVING THE SAME

(71) Applicant: SEOUL VIOSYS CO., LTD., Ansan-si (KR)

(72) Inventor: Jaekwon KIM, Ansan-si (KR)

(21) Appl. No.: 19/366,412

(22) Filed: Oct. 22, 2025

Related U.S. Application Data
(60) Provisional application No. 63/711,664, filed on Oct. 24, 2024.

(51) Int. Cl. H10H 20/857; H10H 20/819; H10H 20/831; H10H 20/858

(52) U.S. Cl. CPC H10H 20/857; H10H 20/819; H10H 20/831; H10H 20/8582

(57) ABSTRACT

A light emitting device including a substrate, a semiconductor layer disposed on the substrate, first and second electrodes disposed on the semiconductor layer, a first insulation layer covering the first and second electrodes and disposed on the semiconductor layer, a first electrode pad electrically connected to the first electrode through a first opening provided in the first insulation layer, and a second electrode pad electrically connected to the second electrode through a second opening provided in the first insulation layer, in which, in the first opening, a distance between an upper surface of the semiconductor layer and an upper surface of the first electrode pad is longer than a maximum distance between the upper surface and a lower surface of the semiconductor layer.

### CROSS REFERENCE TO RELATED APPLICATION

This application claims priority from and the benefit of U.S. Provisional Application No. 63/711,664, filed on Oct. 24, 2024, which is hereby incorporated by reference for all purposes as if fully set forth herein.

### BACKGROUND

### Field

Embodiments of the invention relate generally to a light emitting device and a module having the same.

### Discussion of the Background

A light emitting diode (LED) is a type of a light emitting device that emits light when current is applied. Recently, the light emitting diode has been widely used in various technical fields such as display apparatuses, vehicle lamps, and general lighting. The LED has advantages of long lifespan, low power consumption, and fast response speed, and is rapidly replacing conventional light sources. A display apparatus using light emitting diodes can be obtained by, for example, forming structures of individually grown red (R), green (G), and blue (B) light emitting diodes (LEDs) on a final substrate.

The light emitting diode can be formed by growing epitaxial layers on a substrate, which may include an n-type semiconductor layer, a p-type semiconductor layer, and an active layer interposed therebetween. An n-electrode pad can be formed on the n-type semiconductor layer, and a p-electrode pad can be formed on the p-type semiconductor layer, so that the light emitting diode is driven by electrical connection to an external power source through the electrode pads. In this case, the current can flow from the p-electrode pad through the semiconductor layers to the n-electrode pad, and light generated by recombination of electrons and holes in the active layer can be emitted.

The above information disclosed in this Background section is only for understanding of the background of the inventive concepts, and, therefore, it may contain information that does not constitute prior art.

### SUMMARY

A light emitting device and a module having the same according to embodiments of the invention can simultaneously improve light extraction efficiency, heat dissipation characteristics, current spreading, and mechanical reliability.

A light emitting device and a module having the same according to embodiments of the invention can also prevent electrode lifting or cracking and improve resistance against external moisture penetration, as well as facilitating the manufacturing process and reducing manufacturing costs through a simple structure, thereby ensuring long-term stability of the device.

A light emitting device and a module having the same according to embodiment of the invention have improved performance and reliability.

Additional features of the inventive concepts will be set forth in the description which follows, and in part will be apparent from the description, or may be learned by practice of the inventive concepts.

A light emitting device according to an embodiment of the present disclosure includes a substrate, a semiconductor layer disposed on the substrate, first and second electrodes disposed on the semiconductor layer, a first insulation layer covering the first and second electrodes and disposed on the semiconductor layer, a first electrode pad electrically connected to the first electrode through a first opening provided in the first insulation layer, and a second electrode pad electrically connected to the second electrode through a second opening provided in the first insulation layer.

In the first opening, a distance between an upper surface of the semiconductor layer and an upper surface of the first electrode pad may be longer than a maximum distance between the upper surface and a lower surface of the semiconductor layer.

The semiconductor layer may include a first conductivity type semiconductor layer disposed on the substrate and electrically connected to the first electrode, a second conductivity type semiconductor layer disposed on the first conductivity type semiconductor layer and electrically connected to the second electrode, and an active layer disposed between the first conductivity type semiconductor layer and the second conductivity type semiconductor layer.

The semiconductor layer may have a mesa structure exposing a portion of the first conductivity type semiconductor layer.

A heat transfer path between the first electrode and the mesa structure may be longer than the maximum distance between the upper surface and the lower surface of the semiconductor layer.

A difference between the heat transfer path between the first electrode and the mesa structure and the maximum distance between the upper surface and the lower surface of the semiconductor layer beneath the second electrode may be within 10% of each other.

In the second opening, a distance between the upper surface of the semiconductor layer and an upper surface of the second electrode pad may be shorter than the maximum distance between the upper surface and the lower surface of the semiconductor layer.

In the second opening, the distance between the upper surface of the semiconductor layer and the upper surface of the second electrode pad may be longer than a minimum distance between the upper surface and the lower surface of the semiconductor layer.

A peak wavelength (nm) of light generated in the active layer may be between 0.085 and 0.133 times a distance (μm) from an upper surface of the second conductivity type semiconductor layer to the upper surface of the second electrode pad.

The first insulation layer may include a first insulation sidewall surrounding the second opening and having a height that decreases toward the second opening.

The first insulation sidewall may form an inclined surface having a constant slope.

The first insulation sidewall may include a convex surface.

The upper surface of the second electrode pad disposed over the first insulation sidewall may form an inclined pad surface.

A slope of the inclined pad surface may be constant.

The inclined pad surface may be convex.

The second electrode may include a second electrode sidewall on a side surface thereof.

The second electrode sidewall may form an inclined surface.

The inclined surface of the second electrode sidewall may be concave.

A recess may be provided on an upper surface of the first insulation layer disposed over the second electrode sidewall.

The light emitting device may further include a second insulation layer disposed on the upper surface of the semiconductor layer beneath the second electrode and a contact electrode covering the second insulation layer, the second electrode being disposed on an upper surface of the contact electrode.

The second insulation layer may include a second insulation sidewall on a side surface thereof.

The second insulation sidewall may form an inclined surface.

The inclined surface of the second insulation sidewall may be concave.

The contact electrode may include a contact sidewall on a side surface thereof.

A slope of the contact sidewall may be less than a slope of the second insulation sidewall.

The first insulation layer may include an aluminum oxide layer, and a main insulation layer disposed on the aluminum oxide layer.

The first insulation layer may include a first insulation sidewall surrounding the second opening and having a height that decreases toward the second opening.

The first insulation sidewall may include a convex surface.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic plan view of a light emitting device according to an embodiment of the present disclosure.

FIG. 2 is a cross-sectional view taken along line I-I′ of the light emitting device of FIG. 1.

FIG. 3 is a cross-sectional view taken along line II-II′ of the light emitting device of FIG. 1 according to an embodiment.

FIG. 4 is a partial modified view of FIG. 3 according to another embodiment.

FIG. 5 is another partial modified view of FIG. 3 according to yet another embodiment.

FIGS. 6, 7, 8, and 9 are enlarged cross-sectional views of portions of light emitting devices according to other embodiments of the present disclosure.

FIG. 10 is a schematic plan view of a light emitting device according to another embodiment of the present disclosure.

FIG. 11 is a cross-sectional view taken along direction III-III′ of the light emitting device of FIG. 10.

FIG. 12 is a graph showing peak wavelengths according to current applied to a light emitting device according to an embodiment of the present disclosure.

FIG. 13 is a graph showing driving voltages according to current applied to a light emitting device according to an embodiment of the present disclosure.

FIGS. 14, 15, and 16 are schematic diagrams of light emitting modules including light emitting devices according to the present disclosure.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

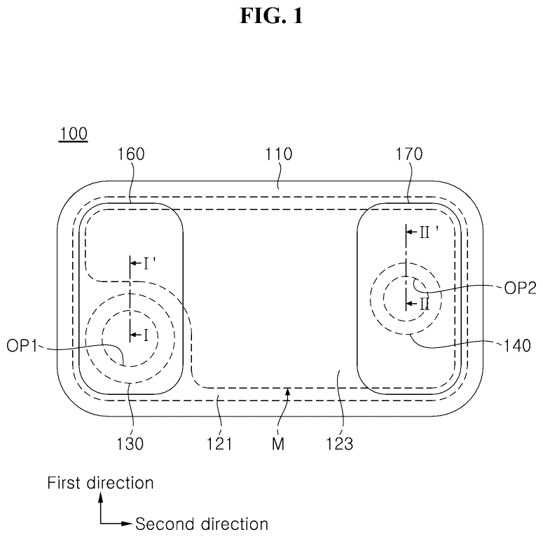

Referring to FIGS. 1 through 3, a light emitting device 100 according to an embodiment of the present disclosure may include a substrate 110, a semiconductor layer 120 disposed on the substrate 110, first and second electrodes 130 and 140 disposed on the semiconductor layer 120, a first insulation layer 150 disposed on the semiconductor layer 120 and covering at least a portion of the first and second electrodes 130 and 140, a first electrode pad 160 electrically connected to the first electrode 130 through a first opening OP1 provided in the first insulation layer 150, and a second electrode pad 170 electrically connected to the second electrode 140 through a second opening OP2 provided in the first insulation layer 150.

The substrate 110 is a layer on which the semiconductor layer 120 is disposed, and is not limited to a particular substrate. For example, the substrate 110 may include a heterogeneous substrate such as a sapphire substrate, a gallium arsenide substrate, a silicon substrate, a silicon carbide substrate, or a spinel substrate, and in addition, may include a homogeneous substrate such as a gallium nitride substrate, an aluminum nitride substrate, or the like. The substrate 110 may be a growth substrate for growing a semiconductor layer thereon. In some embodiments, the substrate 110 may be removed.

A plurality of protrusions P, which is a three-dimensional structure protruding upward, may be formed on a surface of the substrate 110.

The protrusion P may form a roughness on a surface of the substrate 110. Furthermore, the protrusion P may have a micro-structure designed to improve the performance, such as growing a high-quality semiconductor layer 120, improving a light extraction efficiency, stress distribution, and others, of the light emitting device 100.

The protrusions P may be a pattern formed integrally with the substrate 110. The protrusions P may be formed, for example, through etching or patterning a surface of the substrate 110.

Each of the protrusions P may be formed to have various shapes. For example, the protrusions P may have a conical or pyramidal shape with its transverse width gradually narrowing toward the top. The shape of the protrusion P is not limited to a specific form, and it may be implemented in various shapes such as a bell shape with convex side surfaces.

The protrusions P may have various dimensional parameters such as the center-to-center distance (pitch) between adjacent protrusions P, the spacing distance, the maximum width (maximum diameter at the bottom surface), and the height (vertical length from a surface of the substrate 110 to the apex).

The semiconductor layer 120 may include a first conductivity type semiconductor layer 121 disposed on the substrate 110, a second conductivity type semiconductor layer 123 disposed on the first conductivity type semiconductor layer 121, and an active layer 122 disposed between the first conductivity type semiconductor layer 121 and the second conductivity type semiconductor layer 123.

The first conductivity type semiconductor layer 121 may include a phosphide or nitride semiconductor such as (Al, Ga, In) P or (Al, Ga, In) N, and may be disposed on the substrate 110 using a method such as MOCVD, MBE, or HVPE. In addition, the first conductivity type semiconductor layer 121 may be doped as n-type by including one or more impurities such as Si, C, Ge, Sn, Te, Pb, or the like. However, the inventive concepts are not limited thereto, and the first conductivity type semiconductor layer 121 may be doped with an opposite conductivity type including a p-type dopant in other embodiments.

The active layer 122 may be a light emitting layer disposed over the first conductivity type semiconductor layer 121. The active layer 122 may include a phosphide or nitride semiconductor such as (Al, Ga, In) P or (Al, Ga, In) N, and may be grown on the first conductivity type semiconductor layer 121 using a technique such as MOCVD, MBE, HVPE, or the like. In addition, the active layer 122 may include a quantum well structure (QW) including at least two barrier layers and at least one well layer. In some embodiments, the active layer 122 may include a multi quantum well structure (MQW) including a plurality of barrier layers and a plurality of well layers. A wavelength of light emitted from the active layer 122 may be adjusted by controlling a composition ratio of materials forming the well layer.

The second conductivity type semiconductor layer 123 may be a semiconductor layer disposed on the active layer 122. The second conductivity type semiconductor layer 123 may include a phosphide or nitride semiconductor such as (Al, Ga, In) P or (Al, Ga, In) N, and may be grown using a technique such as MOCVD, MBE, HVPE, or the like. The second conductivity type semiconductor layer 123 may be doped with a conductivity type opposite to that of the first conductivity type semiconductor layer 121. For example, the second conductivity type semiconductor layer 123 may be doped as p-type by including an impurity such as Mg.

The semiconductor layer 120 may have a mesa structure M exposing a portion of the first conductivity type semiconductor layer 121. The mesa structure M may be a raised structure formed to electrically isolate the first and second conductivity type semiconductor layers 121 and 123 within the light emitting device 100 and to allow the first and second electrodes 130 and 140 to contact corresponding the first and second conductivity type semiconductor layers 121 and 123.

The mesa structure M may be formed by sequentially growing the first conductivity type semiconductor layer 121, the active layer 122, and the second conductivity type semiconductor layer 123 on the substrate 110, and then removing the second conductivity type semiconductor layer 123 and the active layer 122 from a portion of the semiconductor layer 120 by an etching process, such that a portion of a surface of the first conductivity type semiconductor layer 121 thereunder is exposed.

A region that remains unetched forms a ‘mesa’-shaped structure that is taller than a surrounding area, and an upper surface of the mesa structure M becomes the second conductivity type semiconductor layer 123, while a low and flat region around the mesa structure M becomes an exposed first conductivity type semiconductor layer 121.

The first and second electrodes 130 and 140 are disposed on the semiconductor layer 120 and may be electrically connected to the first and second conductivity type semiconductor layers 121 and 123, respectively.

The first electrode 130 is an electrode electrically connected to the first conductivity type semiconductor layer 121, and may be disposed on a surface of the first conductivity type semiconductor layer 121. The first electrode 130 may be disposed on a low and flat region around the mesa structure M, such as a region where the partial surface of the first conductivity type semiconductor layer 121 is exposed to the outside.

The first electrode 130 may be formed as a single metallic layer, without being limited thereto. In some embodiments, the first electrode 130 may be formed as a multi-layer metal stack in which multiple metals are stacked, in consideration of electrical characteristics, light reflectivity, thermal dissipation performance, and mechanical reliability. For example, the first electrode 130 may include Au, Ni, Ti, Al, Cu, or an alloy thereof.

The second electrode 140 is an electrode electrically connected to the second conductivity type semiconductor layer 123, and may be disposed on a surface of the second conductivity type semiconductor layer 123. The second electrode 140 may be disposed on an upper surface of the mesa structure M, such as an upper surface region of the second conductivity type semiconductor layer 123.

The second electrode 140 may be formed as a single metallic layer, without being limited thereto. In some embodiments, the second electrode 140 may be formed as a multi-layer metal stack in which multiple metals are stacked, in consideration of electrical characteristics, light reflectivity, thermal dissipation performance, and mechanical reliability. For example, the second electrode 140 may include Au, Ni, Ti, Al, Cu, or an alloy thereof.

The first insulation layer 150 is configured to cover at least a portion of the first and second electrodes 130 and 140 and be disposed on the semiconductor layer 120. The first insulation layer 150 may have various configurations. The first insulation layer 150 covers and electrically insulates the semiconductor layer 120 and the first and second electrodes 130 and 140 formed thereon, and at the same time, serves as a support base for the first and second electrodes 160 and 170 to be disposed thereover, thereby improving optical and mechanical characteristics of the light emitting device 100.

The first opening OP1 and the second opening OP2 may be provided in the first insulation layer 150. The first opening OP1 may be positioned over of the first electrode 130. The second opening OP2 may be positioned over the second electrode 140.

The first insulation layer 150 is disposed to cover an upper surface of the second conductivity type semiconductor layer 123, and a partial region of the first conductivity type semiconductor layer 121 exposed by the mesa structure M.

A partial region of the first electrode 130 may be exposed through the first opening OP1, and a partial region of the second electrode 140 may be exposed through the second opening OP2. The first and second openings OP1 and OP2 of the first insulation layer 150 may provide paths through which the first and second electrodes 130 and 140 can be electrically connected to the first and second electrode pads 160 and 170 thereover, respectively.

The first insulation layer 150 may be formed of a dielectric material having insulation characteristics. For example, the first insulation layer 150 may be formed as a single-layer or multi-layer structure including silicon dioxide (SiO₂), silicon nitride (SiNₓ), aluminum oxide (Al₂O₃), or the like.

In addition, the first insulation layer 150 may be formed as a distributed Bragg reflector (DBR) structure, in which materials having different refractive indices, such as silicon dioxide (SiO₂) and titanium dioxide (TiO₂), are alternately stacked to control optical characteristics. Light extraction efficiency may be improved by reflecting light of a particular wavelength band with very high efficiency through the distributed Bragg reflector (DBR) structure.

The first electrode pad 160 is configured to be electrically connected to the first electrode 130 through the first opening OP1 provided in the first insulation layer 150, and various configurations are possible. The first electrode pad 160 may cover the first insulation layer 150 over the first opening OP1, and may be electrically connected to the first electrode 130 through the first opening OP1. The first electrode pad 160 is for connecting an external driving power source through soldering or the like, and may include Au, Ni, Pt, Al, Cu, Ti, or Cr, or an alloy thereof.

The first electrode pad 160 may be formed as a single metallic layer, without being limited thereto. In some embodiments, the first electrode pad 160 may include a multi-layer metal stack in consideration of durability, thermal characteristics, reliability, chemical stability, electrical characteristics, or others.

The second electrode pad 170 is configured to be electrically connected to the second electrode 140 through the second opening OP2 provided in the first insulation layer 150, and various configurations are possible. The second electrode pad 170 may cover the first insulation layer 150 over the second opening OP2, and may be electrically connected to the second electrode 140 through the second opening OP2. The second electrode pad 170 is for connecting an external driving power source through soldering or the like, and may include Au, Ni, Pt, Al, Cu, Ti, or Cr, or an alloy thereof.

The second electrode pad 170 may be formed as a single metallic layer, without being limited thereto. In some embodiments, the second electrode pad 170 may include a multi-layer metal stack in consideration of durability, thermal characteristics, reliability, chemical stability, electrical characteristics, or others.

The first and second electrode pads 160 and 170 may be connected to another substrate, PCB, or the like through soldering. A solder contacting the first and second electrode pads 160 and 170 during soldering may be an alloy material. The alloy material may be superior to a single metal in terms of mechanical strength, thermal characteristics, electrical characteristics, and chemical characteristics. For example, the alloy material may be a material including at least two or more of tin (Sn), silver (Ag), copper (Cu), zinc (Zn), and iron (Fe).

The light emitting device 100 may be formed in a circular or polygonal shape in plan view in a first direction and a second direction, and for example, may be formed in a square shape.

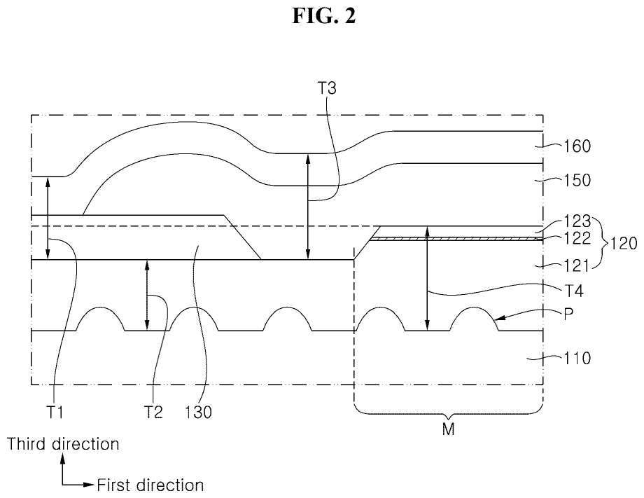

Referring back to FIG. 2, in the first opening OP1, a distance T1 between an upper surface of the semiconductor layer 120 and an upper surface of the first electrode pad 160 may be longer than a maximum distance T2 between the upper surface and a lower surface of the semiconductor layer 120. (T1>T2 relationship)

In particular, the upper surface of the semiconductor layer 120 may be an upper surface of the exposed first conductivity type semiconductor layer 121, and thus, T1 may be defined as a distance from the upper surface of the first conductivity type semiconductor layer 121 to the upper surface of the first electrode pad 160. For example, when the light emitting device 100 is mounted in a flip-chip manner, since a solder bump is formed on the first electrode pad 160, T1 may correspond to a distance from the upper surface of the first conductivity type semiconductor layer 121 to the solder.

A major heat source of the light emitting device 100 is the active layer 122 where current flows to be converted into light. Heat generated in the active layer 122 needs to be quickly dissipated to the outside because it deteriorates the performance of the light emitting device 100 and shortens its lifespan. According to an embodiment, heat generated in the active layer 122 is transferred through the first conductivity type semiconductor layer 121 and the first electrode 130, to the first electrode pad 160 formed of a metallic material with high thermal conductivity and a solder thereon. This path may function as a main thermal dissipation path through which heat escapes. The T1>T2 condition means that a vertical thickness (height) of the first electrode pad 160 and the solder forming the thermal dissipation path is thicker than the thickness T2 of the semiconductor layer 120 where heat is generated. Since this is equivalent to widening a cross-sectional area and increasing a volume of the path through which heat flows, a thermal resistance of an entire thermal dissipation path may be greatly reduced.

Due to the reduced thermal resistance, heat generated in the active layer 122 may be quickly transferred to the first electrode pad 160 and the solder side without a bottleneck phenomenon. The first electrode pad 160 and the solder may themselves serve as an efficient heat sink that absorbs and disperses heat over a wide area. This heat may be dissipated again to an external sub-mount board or printed circuit board connected through the solder.

More particularly, the T1>T2 condition may effectively keep a temperature of the active layer 122 low. This may suppress a thermal droop phenomenon in which luminous efficiency rapidly decreases at high temperatures, thereby maintaining stable light output even when driven at high currents, reducing wavelength changes, and dramatically improving a long-term reliability and lifespan of the light emitting device 100.

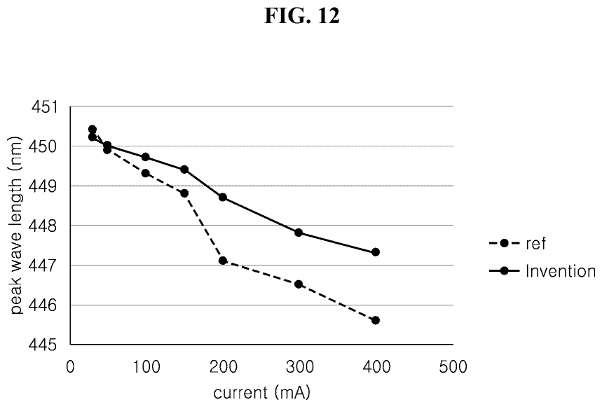

FIG. 12 is a graph showing peak wavelengths (nm) according to the current (mA) applied to the light emitting device 100 according to an embodiment of the present disclosure. In the light emitting device 100, a change in the peak wavelengths with increasing applied current is smaller than that observed in a comparative product (ref). In the comparative product (ref), the change in peak wavelengths with changes in current is relatively large. Accordingly, as the current increases, the wavelength may be blue-shifted, thereby reducing a light efficiency. On the contrary, the light emitting device 100 according to an embodiment of the present disclosure exhibits a very small change of 1 nm or less in the peak wavelengths, when the applied current changes by 100 mA. More particularly, the light emitting device 100 according to an embodiment of the present disclosure has a small rate of changes in the peak wavelengths with increasing current, and a deviation in the rate of changes in the peak wavelengths is also small. Accordingly, color uniformity may be high even when the current applied to the light emitting device 100 changes.

Referring back to FIG. 2, a heat transfer path T3 between the first electrode 130 and the mesa structure M may be longer than the maximum distance T2 between the upper surface and the lower surface of the semiconductor layer 120 beneath the first electrode 130 (T3>T2 relationship).

In particular, the upper surface of the semiconductor layer 120 may be the upper surface of the exposed first conductivity type semiconductor layer 121, and accordingly, T3 may be defined as a vertical distance from the upper surface of the first conductivity type semiconductor layer 121 to the upper surface of the first electrode pad 160 between the first electrode 130 and the mesa structure M. For example, when the light emitting device 100 is mounted in a flip-chip manner, since a solder is disposed on the first electrode pad 160, T3 may correspond to a distance from the upper surface of the first conductivity type semiconductor layer 121 to the solder.

The heat transfer path T3 may refer to an actual length of a path through which heat of the active layer 122, which is the main heat source, ultimately escapes to an external substrate in a region between the first electrode 130 and the mesa structure M.

Heat in the light emitting device 100 is mainly generated in the active layer 122, and in particular, heat generation may be concentrated near an edge of the mesa structure M, where the current density is relatively high. If such heat escapes quickly only through the shortest path, a ‘hot spot’ may form, resulting in localized thermal concentration that can damage semiconductor crystals in a corresponding region or significantly reduce efficiency. According to an embodiment, when the T3>T2 condition is satisfied, heat produced near the edge of the mesa structure M may be guided to spread to a side surface along a longer path T3 first and then dissipated to the outside, rather than escaping only in the vertical direction. This configuration provides a heat spreading effect, allowing heat to be dispersed over a wider region and preventing thermal concentration at a particular point.

Through the heat spreading effect, a temperature distribution within the light emitting device 100 may become uniform overall. In this manner, a performance deviation due to a rise of local temperature may be reduced, thereby ensuring that an entire light emitting device 100 is operated within a stable temperature range.

In addition, a difference between the heat transfer path T3 between the first electrode 130 and the mesa structure M and a maximum distance T4 between the upper surface and the lower surface of the semiconductor layer 120 beneath the second electrode 140 may be within 10% of each other.

In particular, the heat transfer path T3 between the first electrode 130 and the mesa structure M represents the length of a path along which heat is transferred from the active layer 122, which is the main heat source, toward a first electrode 130 side. T4 may be a maximum vertical distance between the upper surface of the second conductivity type semiconductor layer 123 on the mesa structure M and the upper surface of the substrate 110, which may correspond to a thickness of the semiconductor layer 120 on a second electrode 140 side.

By designing different physical parameters of the heat transfer path T3 and the thickness T4 of the semiconductor layer 120 with a margin of less than 10%, it is possible to maintain a balance between the heat transfer paths toward the first electrode 130 and the second electrode 140 sides and to maintain a balance of thermal resistances.

The thermal resistance of the light emitting device 100 quantifies the effectiveness of heat dissipation, and may be proportional to the ‘length of the path’ and inversely proportional to the ‘cross-sectional area of the path’ and a ‘thermal conductivity of a material’. From the first electrode 130 side, since the heat of the active layer 122 spreads in a direction of the side surface and then escapes through the electrode, T3 may be a variable that determines the thermal resistance. In addition, from the second electrode 140 side, the heat of the active layer 122 passes vertically to be transferred, and since the semiconductor layer 120 has a much lower thermal conductivity than that of the second electrode 140 including metal, the semiconductor layer 120 may be a variable that determines the thermal resistance.

By designing the heat transfer path length T3 on the first electrode 130 side and the thickness T4 of the semiconductor layer 120 that affects the thermal resistance on the second electrode 140 side with the margin of less than 10%, an overall thermal resistance of two main thermal dissipation paths according to an embodiment may become similar. In this manner, heat flow may be symmetrically controlled to achieve heat balance, and a uniform thermal dissipation and a very uniform temperature distribution across the entire light emitting device 100 may be achieved. As a result, an occurrence of local hot spots may be suppressed, and an occurrence of non-uniform stress due to heat may be minimized. This may stably maintain the performance of the active layer 122 which is sensitive to temperatures, and prevent physical damage (e.g., peeling, cracking) due to thermal stress, thereby improving the reliability and lifespan of the light emitting device 100.

In addition, in the second opening OP2, a distance T6 between the upper surface of the semiconductor layer 120 and an upper surface of the second electrode pad 170 may be shorter than the maximum distance T4 between the upper surface and the lower surface of the semiconductor layer 120. (T6<T4 condition)

In particular, the upper surface of the semiconductor layer 120 may be the upper surface of the second conductivity type semiconductor layer 123 on the mesa structure M, and the maximum distance T4 may refer to a total thickness of a semiconductor stack structure.

The T6<T4 relationship is an opposite relationship to that of a structure (T1>T2) around the first electrode 130 discussed above. In this manner, a current injection efficiency may be increased and a driving voltage may be reduced.

The second conductivity type semiconductor layer 123 may be a p-GaN layer, and in this case, the electrical conductivity thereof may be lower than an n-GaN layer of the first conductivity type semiconductor layer 121. In this case, forming an ohmic contact with the electrode becomes more difficult. Accordingly, whether current is efficiently injected into the semiconductor layer without loss on the second electrode 140 side should be considered.

The T6<T4 condition may shorten an electrical path length from an external power source to the second conductivity type semiconductor layer 123. This may have an effect of reducing a series resistance. As the resistance decreases, a driving voltage (Vf, forward voltage) required to produce the same amount of light may be lowered. When the driving voltage becomes lower, a power consumption of the device is reduced, and as a result, wall-plug efficiency (WPE) may be improved.

More particularly, by applying a design that maximizes thermal dissipation function on the first electrode 130 side and by applying a complementary design that maximizes electrical characteristics (low resistance, improved current injection) on the second electrode 140 side, it is possible to simultaneously improve both performances of thermal dissipation and efficiency.

In this case, in the second opening OP2, the distance T6 between the upper surface of the semiconductor layer 120 and the upper surface of the second electrode pad 170 may be longer than a minimum distance T5 between the upper surface and the lower surface of the semiconductor layer 120.

In particular, the minimum distance T5 may be a vertical distance from a highest point of the protrusions P of the substrate 110 to the upper surface of the second conductivity type semiconductor layer 123. This may correspond to a thickness of a thinnest portion of the semiconductor layer 120 on the mesa structure M.

Accordingly, the second electrode pad 170 side may have a thickness relationship of T5<T6<T4. In this manner, a thickness of the second electrode pad 170 may be sufficiently secured, and the reliability may be ensured. When T6 is thinner than the thickness T5 of the thinnest portion of the semiconductor layer 120, a mechanical strength of the second electrode pad 170 itself may be weakened and a current capacity may be insufficient. This may lead to physical damage to the second electrode pad 170 when connected to the outside, or to breakage (burnout) of the second electrode pad 170 when driven by high current.

The T6>T5 condition may ensure that even when a height of the second electrode pad 170 is lowered to increase the current injection efficiency, the second electrode pad 170 has a minimum thickness sufficient to perform mechanically and electrically stable functions. This may increase the efficiency of the light emitting device 100 without compromising reliability.

In addition, by precisely controlling T6 to a predetermined value between a maximum thickness T4 and a minimum thickness T5 of the semiconductor layer 120, an overall resistance value of a path passing through the second electrode 140 may be finely tuned. This may achieve improved current spreading across the entire light emitting device 100.

Accordingly, through the condition of T5<T6<T4, structural stability and reliability of the second electrode pad 170 may be ensured while achieving low driving voltage and high current injection efficiency of a path passing through the second electrode pad 170.

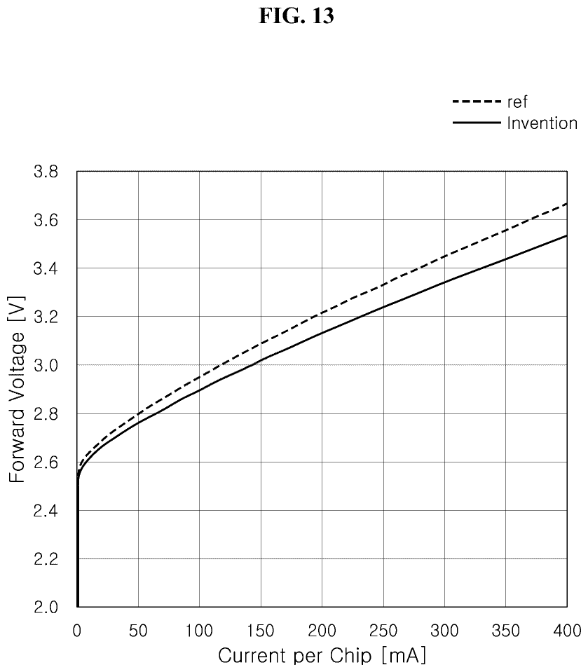

FIG. 13 is a graph showing a change in driving voltages (Vf) according to the current applied to the light emitting device 100 according to an embodiment of the present disclosure described above. In the case of the light emitting device 100 according to an embodiment of the present disclosure, a rate of increase in the driving voltages (Vf) and a rate of change in the driving voltages with an increasing applied current are smaller than those of the comparative product (ref). In the case of the comparative product (ref), since the rate of increase and the rate of change in the driving voltages (Vf) according to the current change is large, a voltage response according to the current change may become unstable or sensitive, the power efficiency may decrease, and the heat generation may increase, thereby decreasing its reliability and reducing its lifespan. On the contrary, the light emitting device 100 according to an embodiment of the present disclosure exhibits a very small change of 0.23 V or less in driving voltages (Vf) when the applied current changes by 100 mA. More particularly, the light emitting device 100 according to an embodiment of the present disclosure has a small increase rate and change rate of the driving voltages (Vf) according to the increase in current, and a deviation in the change rate of the driving voltage (Vf) is also small. Accordingly, the power efficiency and the reliability are high and the light emitting device 100 may be operated stably for a long period of time even when the current applied to the light emitting device 100 changes.

Meanwhile, a peak wavelength (nm) of light generated in the active layer 122 may be between 0.085 and 0.133 times the distance T6 (μm) from the upper surface of the second conductivity type semiconductor layer 123 to the upper surface of the second electrode pad 170.

An interior of the light emitting device 100 has a structure in which several thin layers (thin film layers) are stacked, which may function as a type of optical cavity or wavelength filter. When light generated in the active layer 122 is reflected from a surface of the second electrode pad 170 and returns toward the active layer 122, if constructive interference is caused with an original light depending on a condition, a light output in a particular direction (mainly a vertical direction) may be increased.

Through numerical design of the T6, an optical distance at which light of a target peak wavelength causes the constructive interference inside the light emitting device 100 may be implemented. More particularly, the second electrode 140 and the second electrode pad 170 may function as elements that control not only electrical terminals but also optical performance.

An optimal height T6 of the second electrode 140 and the second electrode pad 170 may be calculated inversely according to a target peak wavelength of the light emitting device 100 (e.g., blue, green, or red), and the light extraction efficiency may be maximized.

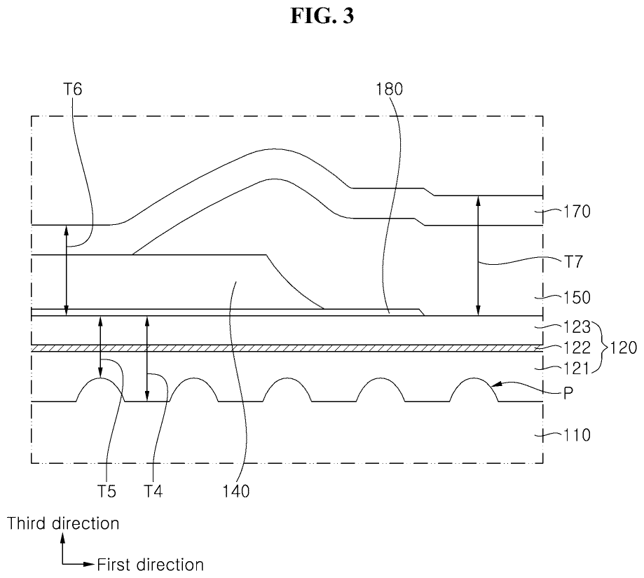

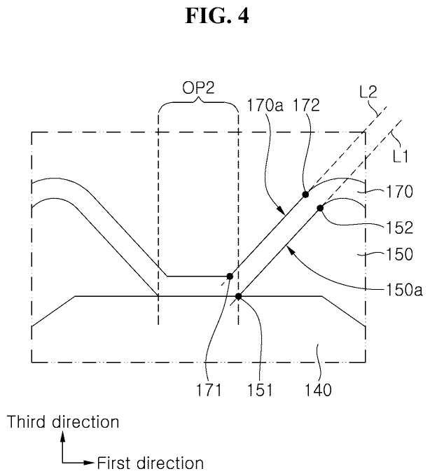

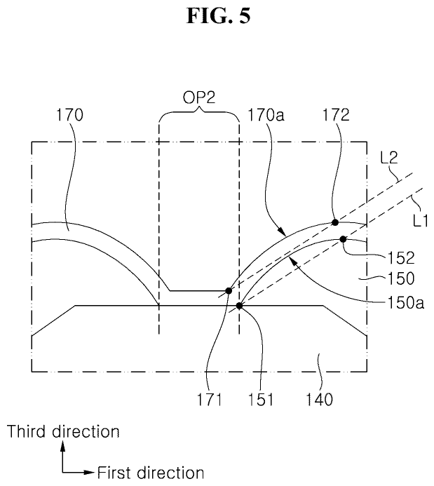

FIGS. 4 and 5 are partial modified views of FIG. 3 according to embodiments of the present disclosure.

Referring to FIG. 4, the first insulation layer 150 may include a first insulation sidewall 150a surrounding the second opening OP2 and having a height that becomes lower as it gets closer to the second opening OP2. An inclined structure of the first insulation sidewall 150a may assist to stably form the second electrode pad 170 to be deposited thereover and may alleviate stress concentration.

For example, the first insulation sidewall 150a may form a flat inclined surface having a constant slope. This inclined surface may coincide with an imaginary straight line L1 connecting a first point 151 in a lower portion where the first insulation sidewall 150a meets the second electrode 140 thereunder and a second point 152 which is an upper corner of the first insulation sidewall 150a. Such a linear inclined surface has a relatively simple manufacturing process, and may improve stress distribution and step coverage compared to a vertical step structure. The second point 152 may be a point where a linear side surface and a curved side surface of the first insulation layer 150 meet.

As another example, referring to FIG. 5, the first insulation sidewall 150a may include a convex surface. The convex surface may be a gently curved surface that protrudes outward (outer side) from the imaginary straight line L1 connecting the first point 151 and the second point 152. Such a convex surface structure may disperse stress, improve thermal dissipation characteristics, and increase light reflection efficiency. The second point 152 may be a vertex of the first insulation layer 150 that is vertically overlapped with the second electrode 140.

The convex surface such as that shown in FIG. 5 may smoothly connect the first insulation sidewall 150a to eliminate a point where stress may be concentrated. In this manner, resistance to thermal stress or external impact may be maximized, cracks or peeling of the second electrode pad 170 may be effectively prevented, and the reliability of the light emitting device 100 may be improved.

In addition, a total surface area of the first insulation sidewall 150a is increased through the convex surface, and the increased surface area may expand a contact area with other materials, thereby facilitating thermal dissipation. In this manner, a thermal dissipation performance of the light emitting device 100 may be improved.

In addition, the convex surface may reflect light incident at various angles over a wider range. This may improve light extraction efficiency by increasing a probability that light proceeding to the side surface is reflected through multiple paths rather than being focused in a particular direction.

According to another embodiment, the upper surface of the second electrode pad 170 disposed over the first insulation sidewall 150a shown in FIG. 4 may form an inclined pad surface 170a. For example, a slope of the inclined pad surface 170a may be constant. The inclined pad surface 170a may coincide with an imaginary straight line L2 connecting a first point 171 in a lower portion, and a second point 172 which is an upper corner.

According to yet another embodiment, the inclined pad surface 170a shown in FIG. 5 may be a convex. The convex surface may be a gently curved surface that protrudes outward (outer side) from the imaginary straight line L2 connecting the first point 171 and the second point 172.

When the first insulation sidewall 150a in the lower portion forms a linear inclined surface as shown in FIG. 4, a slope of the inclined pad surface 170a may also be constant. In particular, the inclined pad surface 170a forms a flat linear inclined surface. When the first insulation sidewall 150a in the lower portion forms a convex surface as shown in FIG. 5, the inclined pad surface 170a may also be a convex.

When the second electrode pad 170 has a gentle slope or curve surface, stress may be reduced and the solder may be naturally and stably flow and settle due to surface tension, thereby improving the yield of the external connection process and the reliability of the final joint. In addition, the inclined pad surface 170a may form the uppermost metal structure of the device, which may affect reflection characteristics of light directed upward from the inside of the light emitting device 100 or light incident from the outside. By precisely controlling an angle and a curvature of the inclined pad surface 170a, it is possible to induce light reflection in a particular direction or cause diffuse reflection to implement desired light distribution characteristics. In particular, the inclined pad surface 170a of a convex curved shape may disperse light at a wider angle to reduce glare or increase light emission uniformity.

In addition, since the inclined pad surface 170a has a smooth shape, it is possible to prevent stress from being concentrated at an edge of the electrode pad itself. This may have an effect of enhancing an overall durability of the device by preventing the electrode pad from being damaged by physical pressure applied during a packaging process or by thermal stress generated during long-term use.

Meanwhile, the slopes of L1 and L2 may be different from each other. An inclination of L2 may be formed independently from L1. For example, L2 may have the inclination steeper than L1. In this manner, it is possible to improve precision in electrode formation, control an optical path in multi-stage steps, and relieve stress step-by-step.

Referring back to FIG. 3, the light emitting device 100 may further include a contact electrode 180. The contact electrode 180 may be an ohmic electrode that directly contacts the upper surface of the second conductivity type semiconductor layer 123 on the mesa structure M, and various configurations are possible. The second electrode 140 may be disposed on the contact electrode 180.

The contact electrode 180 may be disposed between the second electrode 140 and the second conductivity type semiconductor layer 123, thereby optimizing the electrical characteristics therebetween and increasing an optical efficiency.

The contact electrode 180 may be formed of a transparent electrode through which light can pass. For example, indium tin oxide (ITO), zinc oxide (ZnO), or the like may be used as the contact electrode 180.

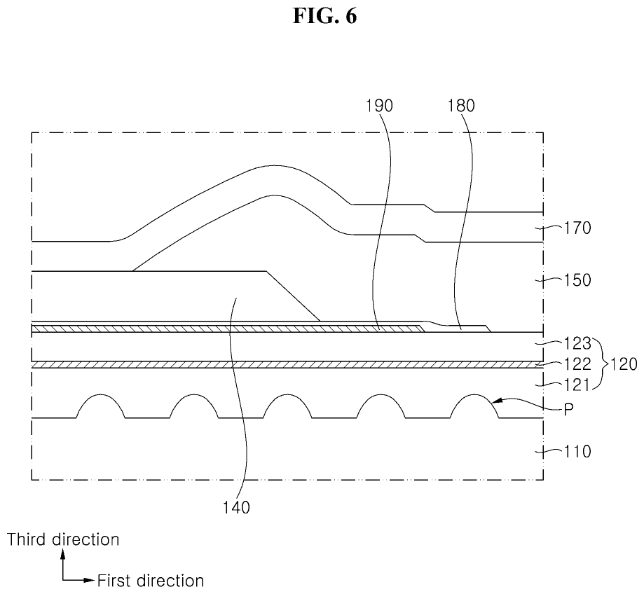

FIG. 6 is a cross-sectional view showing a portion of a light emitting device 100 according to another embodiment of the present disclosure. The light emitting device 100 schematically shown in FIG. 6 may be configured in a same manner as that of the light emitting device 100 of FIG. 1, except that it further includes a second insulation layer 190 disposed on the upper surface of the semiconductor layer 120 beneath the second electrode 140.

The second insulation layer 190 may be disposed to cover most of the upper surface of the second conductivity type semiconductor layer 123. The second insulation layer 190 may have electrical insulation characteristics.

In this case, the contact electrode 180 covers the second insulation layer 190, and the second electrode 140 may be disposed on an upper surface thereof. The contact electrode 180 may not be in direct contact with an entire second conductivity type semiconductor layer 123, but may be isolated from most of a region by the second insulation layer 190. The contact electrode 180 extends downward through an edge of the second insulation layer 190, and may be in direct contact with an edge region of the second conductivity type semiconductor layer 123 that is not covered by the second insulation layer 190.

Since the second insulation layer 190 functions as a barrier through which the current cannot flow, the current supplied from the second electrode 140 through the contact electrode 180 cannot be directly injected into a center of the second conductivity type semiconductor layer 123, but may be injected into the semiconductor layer 120 only through the edge region where the second insulation layer 190 is absent. This may cause a ‘current confinement’ or ‘current aperture’ effect that restricts the current injection path to the edge of the device. As a current injection region is limited to the edge, light emission in the active layer 122 may also mainly occur intensively in a corresponding region. By keeping a physical distance between light generated from metallic electrode layers (the contact electrode 180 and the second electrode 140) that may absorb or block light, a probability of light being absorbed by metal may be significantly reduced and a probability of light being extracted to the outside may be increased. Accordingly, the light extraction efficiency may be improved.

In addition, the second insulation layer 190 physically isolate a large region between the contact electrode 180 and the second conductivity type semiconductor layer 123, and thus, a leakage current path that is likely to occur due to interface defects and the like may be blocked, and the electrical stability and reliability of the light emitting device 100 may be increased.

The second insulation layer 190 may be formed as a single insulation layer or a distributed Bragg reflector (DBR). For example, the second insulation layer 190 may be a DBR formed by alternately stacking silicon dioxide (SiO₂) having a low refractive index and titanium dioxide (TiO₂) or tantalum pentoxide (Ta₂O₅) having a high refractive index. In this case, light generated in the active layer 122 may be efficiently reflected from the DBR and directed to the outside, thereby improving the light extraction efficiency.

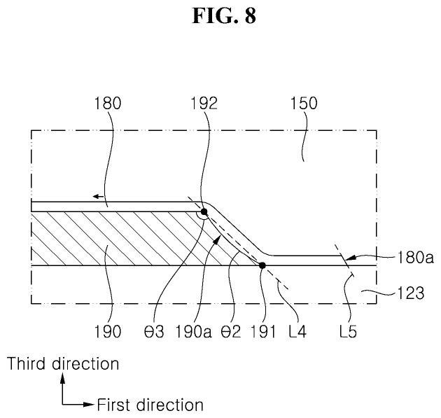

Referring to FIG. 8, the second insulation layer 190 may include a second insulation sidewall 190a on a side surface thereof. The second insulation sidewall 190a may form an inclined surface. For example, the inclined surface of the second insulation sidewall 190a may be concave.

The inclined surface of the second insulation sidewall 190a may have a smooth curved shape that is recessed inward with respect to an imaginary straight line L4 connecting a lower point 191 and an upper point 192. The concave second insulation sidewall 190a enables a sidewall length of the contact electrode 180 deposited thereon to be secured longer. When a sidewall length of the contact electrode 180 increases, the current spreading effect may be improved, so that a phenomenon of current being crowded at a particular point may be alleviated and more uniform light emission may be induced in the entire active layer 122, thereby the efficiency and reliability of the light emitting device 100 may be improved.

In addition, the concave second insulation sidewall 190a may have a sum of an angle θ2 geometrically formed at the lower point 191 and an angle θ3 formed at the upper point 192 that is less than 180° (θ2+θ3<180°). In this manner, the second insulation sidewall 190a has a stable inclined structure without an overhang or re-entrant profile, so that when the contact electrode 180 is deposited in a subsequent process, the second insulation sidewall 190a may be stably covered with a uniform thickness on the second insulation layer 190. Accordingly, disconnection defects may be prevented and a yield of the manufacturing process may be increased.

That is, a concave sidewall structure of the second insulation layer 190 shown in FIG. 8 may improve the electrical characteristics (current spreading) of the device by increasing an effective length of the contact electrode 180, and at the same time, it is possible to enable stable deposition of the contact electrode 180, thereby ensuring the manufacturing reliability.

In addition, in FIG. 8, the contact electrode 180 may include a contact sidewall 180a on a side surface thereof. A slope of the contact sidewall 180a (a slope of an imaginary straight line L5 extending along the contact sidewall 180a) may be less than that of the second insulation sidewall 190a. Herein, the slope of the second insulation sidewall 190a may be defined as a slope of L4. By making the slope of L5 smaller than the slope of L4, it is possible to prevent the resistance from changing rapidly at an outer periphery portion of the contact electrode 180.

When the current is injected into the second conductivity type semiconductor layer 123 through the contact electrode 180, the current is likely to flow along a path with a lowest resistance. If an edge of the contact electrode 180 is sharp or has a steep inclination, the current may be crowded at a corresponding corner, which may cause an increased local resistance and heat generation, thereby lowering the efficiency and reliability of the device. When the contact sidewall 180a is formed with a gentle inclination (L5<L4), a cross-sectional area of the outer periphery portion of the contact electrode 180 gradually changes, which may prevent the resistance in the outer periphery portion of the contact electrode 180 from changing abruptly. In particular, the current may be induced to flow more smoothly rather than being crowded in a particular corner. As a result, the current density distribution may become uniform, and local heat generation and deterioration phenomena may be suppressed, thereby improving the electrical stability and lifespan of the light emitting device 100.

In addition, the gentle inclination of the contact sidewall 180a may enable the second electrode 140 which will be deposited thereon to be stably formed with a uniform thickness without interruption. This may increase the reliability and yield of the manufacturing process.

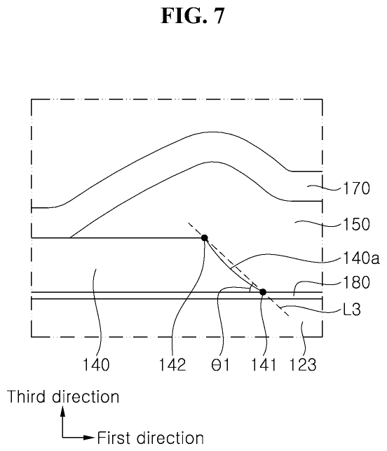

Next, referring to FIG. 7, the second electrode 140 may include a second electrode sidewall 140a on a side surface thereof. The second electrode sidewall 140a may form an inclined surface. For example, the inclined surface of the second electrode sidewall 140a may be concave. Alternatively, the inclined surface of the second electrode sidewall 140a may be convex. Still alternatively, the inclined surface of the second electrode sidewall 140a may include both the convex surface and the concave surface. In particular, the second electrode sidewall 140a may form an inclined surface including a complex curved surface rather than a flat linear inclined surface. For example, the inclined surface of the second electrode sidewall 140a may be a complex curved surface (such as an S-shape or the like) that includes both the convex surface and the concave surface.

The inclined surface of the second electrode sidewall 140a may have a smooth curved shape that is recessed or protruded inward with respect to an imaginary straight line L3 connecting a lower point 141 and an upper point 142. By forming the second electrode sidewall 140a to include a curved surface, a surface area of the second electrode 140 may be increased, thereby preventing a phenomenon of a corner at an outer periphery of the second electrode 140 being lifted due to thermal expansion stress.

An edge of the second electrode 140 is a vulnerable point where thermal stress is most concentrated at an interface with an underlying layer (an insulation layer or a semiconductor layer) having a different thermal expansion coefficient. When the light emitting device 100 is repeatedly operated, the phenomenon of the corner at the outer periphery of the second electrode 140 being lifted or peeled off may occur due to the thermal stress, which may be a main cause of a failure of the light emitting device 100. According to an embodiment, by forming the second electrode sidewall 140a to have a curved surface rather than a straight line, a total surface area of the electrode may be increased. The increased surface area may increase a contact area with the underlying layer, thereby enhancing a physical bonding strength. At the same time, the smooth curve allows stress to be dispersed over a wider region rather than being concentrated at a particular corner. Accordingly, the phenomenon of the corner of the second electrode 140 being lifted due to the thermal expansion stress may be fundamentally prevented, and a long-term durability and reliability of the device may be improved.

Furthermore, since light reflection and scattering characteristics change depending on a curvature (concave, convex, or others) of the second electrode sidewall 140a, a light extraction path may be controlled through the curvature. In addition, the increased surface area of the second electrode sidewall 140a may also contribute to improving thermal dissipation performance.

In this case, a recess may be provided on an upper surface of the first insulation layer 150 disposed over the second electrode sidewall 140a. This recess refers to a structure in which a flat upper surface of the first insulation layer 150 is locally sunken into a valley or concave shape. This may be formed along the edge of the second electrode 140.

One of the main factors that impedes the reliability of the light emitting device 100 is that external moisture (H₂O) penetrates into the device to corrode the electrode or deteriorate the semiconductor layer. Moisture may diffuse mainly along an interface between heterogeneous materials. A recess structure of the first insulation layer 150 may physically increase a surface length of the first insulation layer 150. When moisture from the outside penetrates along the interface of the first insulation layer 150, a path that moves along the recess may become much longer and more complex than a path on a flat surface. As described above, by making a moisture penetration path longer through the recess, a time it takes for moisture to reach a sensitive active region inside the device may be delayed and an amount of penetrated moisture itself may be reduced. This may significantly improve a moisture resistance of the light emitting device 100, ensuring high reliability that allows for long-term stable operation even in high temperature and high humidity environments.

In addition, in a case that the first insulation layer 150 has a DBR structure or is formed of materials having a high refractive index difference, a shape of the recess may affect optical characteristics. As such, it is possible to achieve reflection at multiple angles, and diffuse reflection may be induced, thereby increasing a reflection efficiency in the first insulation layer 150 and improving the light extraction efficiency.

FIG. 7 is a representative illustration of the sidewall 140a of the second electrode 140, but the inventive concepts are not limited thereto. In some embodiments, the first electrode 130 may also have a side inclined surface including a concave, convex, or complex curved surface, similar to that of the second electrode 140. In this manner, mechanical reliability and thermal dissipation characteristics of the first electrode 130 may also be improved under substantially the same principle.

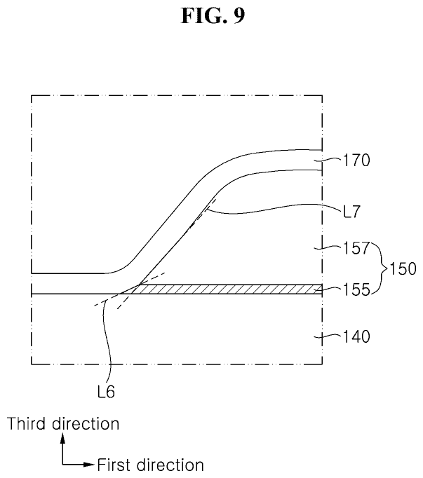

FIG. 9 is a diagram showing an enlarged portion of a light emitting device 100 according to another embodiment of the present disclosure, and the light emitting device 100 may be configured similarly to the light emitting device 100 of FIGS. 1 and 6, except that the first insulation layer 150 includes an aluminum oxide layer 155 and a main insulation layer 157 disposed on the aluminum oxide layer 155.

The main insulation layer 157 is a layer that performs a major function of the first insulation layer 150 described above, and may be configured identically or similarly thereto. For example, the main insulation layer 157 provides electrical insulation, and in particular, may be formed as a DBR (distributed Bragg reflector) layer.

The aluminum oxide layer 155 may be disposed between the second electrode 140 thereunder and the main insulation layer 157 thereover. For example, the aluminum oxide layer 155 may be first deposited on the second electrode 140, and then the main insulation layer 157 may be deposited thereon. The aluminum oxide layer 155 may be a layer that includes Al₂O₃, for example.

By inserting the aluminum oxide layer 155 in the middle, cracks may be prevented and mechanical reliability may be improved. The aluminum oxide layer 155 may function as a buffer layer or a shaping layer forming a gentle profile. More particularly, a slope of the entire first insulation layer 150 may be varied from L6 to L7, with an interface between the aluminum oxide layer 155 and the main insulation layer 157 as a boundary.

A gentle lower inclination L6 formed by the aluminum oxide layer 155 and a relatively steep upper inclination L7 of the main insulation layer 157 formed thereon are coupled to prevent a sudden change in inclination of the surface of the first insulation layer 150 on which the second electrode pad 170 is to be disposed. In this manner, stress concentration may be effectively alleviated, so that a crack occurrence in the second electrode pad 170 may be prevented, and the mechanical durability of the device may be greatly improved.

In addition, when the main insulation layer 157 is formed as a DBR layer including a high refractive index layer (e.g., Tio₂) and a low refractive index layer (e.g., SiO₂), a refractive index (approximately 1.77) of aluminum oxide (Al₂O₃) may have a value higher than that (approximately 1.46) of the low refractive index layer SiO₂ and lower than that (approximately 2.4) of the high refractive index layer TiO₂. Therefore, the aluminum oxide layer 155 may allow more light to be efficiently reflected without loss. This may increase light transmittance and improve overall light extraction efficiency.

FIG. 9 is a representative illustration of a multilayer structure of the first insulation layer 150 disposed over the second electrode 140, but the inventive concepts are not limited thereto. In some embodiments, the first insulation layer 150 having similar or identical multilayer structure may also be applied to structure disposed over the first electrode 130 to improve mechanical reliability and optical characteristics.

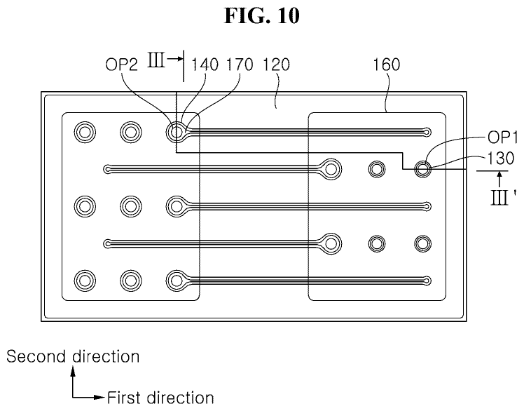

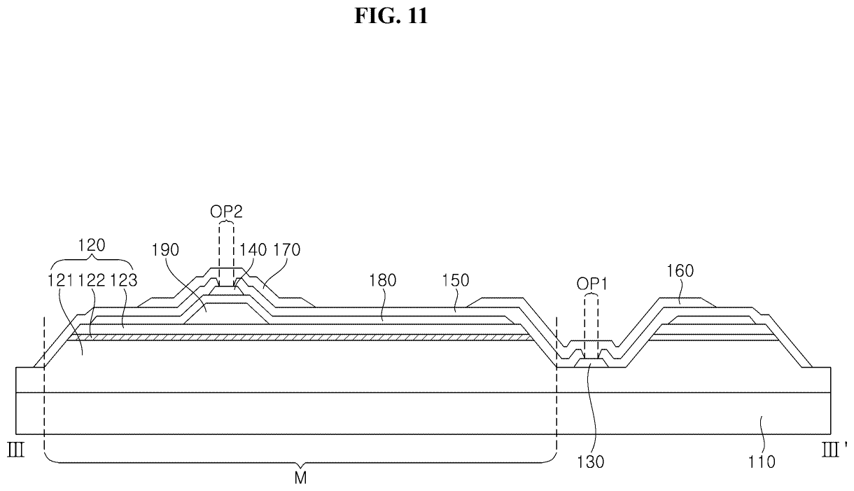

FIG. 10 is a plan view of a light emitting device 100 according to another embodiment of the present disclosure, and FIG. 11 is a cross-sectional view showing the light emitting device 100 of FIG. 10 along a direction III-III′.

Referring to FIGS. 10 and 11, the light emitting device 100 may have a structure in which electrodes are disposed within a plurality of via-holes. A first electrode pad 160 and a second electrode pad 170 may be electrically connected to a semiconductor layer 120 in a lower portion through their respective openings OP1 and OP2.

A second electrode 140 may include an extension part extending along a first direction from a head which is the main body. The extension part of the second electrode 140 may start from the head of the second electrode 140, and extend lengthily toward another electrode, a first electrode 130, or to a space therebetween.

Since the extension part of the second electrode 140 serves as a main path through which current flows, it may have a line or strip shape that is significantly narrower and longer than a head portion. In this manner, the current may be transferred as far as possible within a limited space.

As a size of the light emitting device 100 increases, it may be difficult to uniformly supply the current to a region far from the second electrode 140. In particular, on a second conductivity type semiconductor layer 123 with high resistance, a ‘current crowding phenomenon’ in which the current remains only around the electrodes may be aggravated. The extension part according to an embodiment of the present disclosure may function as a ‘current highway’. By forming the extension part with a metallic material having very low resistance, the current may be quickly transferred from the head of the electrode 140 to a center or a distant region of the device with little loss. The transferred current may spread again over a wide region around the extension part and be injected into the semiconductor layer 120.

A structure of the extension part of the second electrode 140 enables effective injection of current even into a semiconductor region far from the second electrode 140. This may make a current density distribution very uniform across the entire light emitting device 100, thereby allowing light to be generated with uniform brightness in the entire active layer 122. As a result, an overall light output of the light emitting device 100 may be significantly improved without local heat generation or efficiency reduction.

In addition, as the current spreads rather than being crowded at a particular point, a risk of device deterioration or damage due to local overheating may be significantly reduced. This may ensure a long-term reliability and lifespan of the light emitting device 100.

An end of the extension part may include a round region in which a width is widened again to prevent damage (carbonization) of the electrode due to a rapid current gathering. This may make a current flow much smoother and increase its stability at the end.

A structure of the second electrode 140 having the extension part illustrated in FIGS. 10 and 11 may actively control the flow of current through a geometric design of a metallic pattern, and through this, current uniformity may be achieved even in a large-area light emitting device 100.

In addition, referring to FIGS. 10 and 11, the light emitting device 100 may include a plurality of via-holes exposing a first conductivity type semiconductor layer 121.

The via-holes may have different sizes, areas, or shapes from one another. For example, widths (head diameter) of via-holes (left via-holes in FIG. 10) near an outer periphery of the light emitting device 100 may be formed larger than those of via-holes in a center or other sides. In this manner, a wider active layer 122 may be secured in an outer periphery region, thereby increasing an amount of light emitted to a side surface of the substrate 110.

In addition, a width of the first electrode 130 disposed within each of the via-holes may also vary depending on a position. In particular, an electrode with a large width may be disposed in a wide via-hole, and an electrode with a small width may be disposed in a narrow via-hole. By intentionally designing the sizes of via-holes and electrodes to vary depending on their positions, a contact resistance in each region may be finely adjusted. This may allow the current to be spread more evenly across the entire light emitting device 100 rather than being crowded at a particular point.

In addition, arrangements of the first and second electrodes 130 and 140 may have directionality.

As illustrated in FIG. 10, a plurality of the first and second electrodes 130 and 140 may be arranged along a first direction (transverse direction) and a second direction (vertical direction) perpendicular thereto. In this case, a separation distance between the electrodes in the first direction may be smaller than a separation distance in the second direction. More particularly, the first and second electrodes 130 and 140 may be arranged more densely in the first direction. Such an arrangement may induce the current to flow more easily mainly in the first direction (e.g., in a direction toward the first electrode 130). This may give directionality to a main flow of the current, thereby optimizing a current path and reducing power loss.

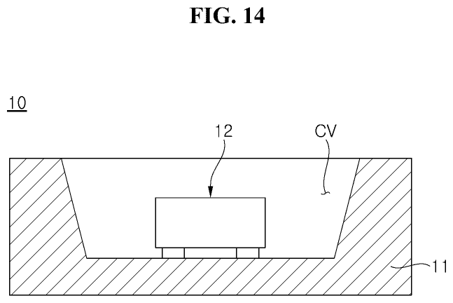

FIGS. 14 through 16 are schematic diagrams showing various applications of light emitting modules including the light emitting device 100 described above. The light emitting device 100 according to embodiment is not limited to a specific use based on its optical, thermal, and mechanical characteristics, and may be widely applied to all technical fields requiring light.

FIG. 14 is a schematic cross-sectional view showing an example of a light emitting apparatus 10 to which the light emitting device 100 according to an embodiment of the present disclosure is applied.

Referring to FIG. 14, the light emitting apparatus 10 may include a package body 11, and the light emitting device 100 mounted therein. The package body 11 is generally formed of ceramic, PCB, or metal material to protect the light emitting device 100 from an external environment, and effectively dissipate generated heat. The light emitting device 100 may be mounted in a cavity CV formed on a bottom surface of the package body 11 through soldering or die attach. An interior of the cavity CV and an upper portion of the light emitting device 100 may be filled with a light-transmitting resin (e.g., silicone or epoxy). As described above, the light emitting device 100 according to an embodiment of the present disclosure may be used as a light source of a basic LED package, and may become a basic unit for configuring a single light source or a multi-chip light source.

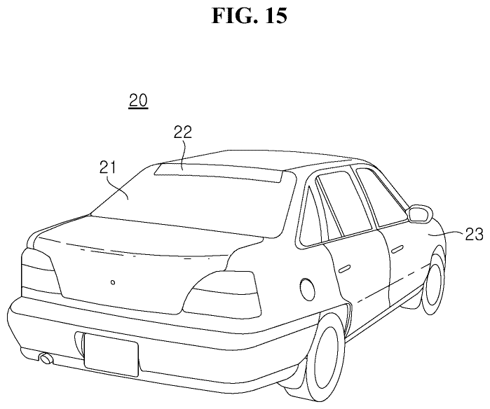

FIG. 15 is a schematic diagram showing an example of a vehicle 20 to which the light emitting device 100 according to an embodiment of the present disclosure is applied.

External lighting apparatuses 23 such as headlamps, tail lamps, turn signals, and daytime running lights (DRL) of the vehicle 20, or internal lighting apparatuses such as instrument panels and interior lights require light sources with high reliability and high brightness. The light emitting device 100 according to embodiments of the present disclosure has excellent thermal dissipation characteristics and mechanical durability, so that it may be operated stably for a long period of time even in a vehicle environment with a lot of vibration and extreme temperature changes.

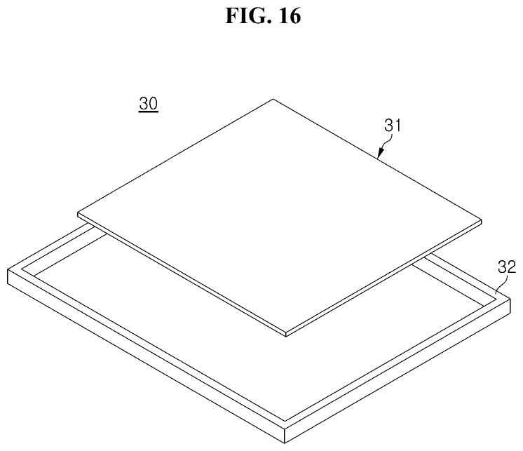

FIG. 16 is a schematic diagram showing an example of a module apparatus 30 to which the light emitting device 100 according to an embodiment of the present disclosure is applied.

The module apparatus 30 may include a module substrate 31 that displays an image and a sub-structure 32 that supports and drives the module substrate 31. The light emitting device 100 according to embodiments of the present disclosure may be applied as a white light source, a backlight unit (BLU) light source, or a self-luminous pixel in such a module apparatus.

The light emitting device 100 according to embodiments of the present disclosure may have a high versatility that may be used as a core component in a wide range of applications, including LED packages, light source modules for general lighting or special lighting, and high-resolution display apparatuses, without being limited to specific uses. The embodiments of the present disclosure may provide a light emitting device and a module having the same which can simultaneously improve light extraction efficiency, heat dissipation characteristics, current spreading, and mechanical reliability.

Furthermore, the embodiments of the present disclosure may provide a light emitting device and a module having the same which can prevent electrode lifting or cracking and improve resistance against external moisture penetration, as well as facilitating a manufacturing process and reducing manufacturing costs through a simple structure, thereby ensuring long-term stability of the device.

The embodiments of the present disclosure may provide a light emitting device and a module having the same having improved performance and reliability.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A light emitting device, comprising:
a substrate;
a semiconductor layer disposed on the substrate;
first and second electrodes disposed on the semiconductor layer;
a first insulation layer covering the first and second electrodes and disposed on the semiconductor layer;
a first electrode pad electrically connected to the first electrode through a first opening provided in the first insulation layer; and
a second electrode pad electrically connected to the second electrode through a second opening provided in the first insulation layer,
wherein, in the first opening, a distance between an upper surface of the semiconductor layer and an upper surface of the first electrode pad is longer than a maximum distance between the upper surface and a lower surface of the semiconductor layer.

2. The light emitting device of claim 1, wherein:
the semiconductor layer includes a first conductivity type semiconductor layer disposed on the substrate and electrically connected to the first electrode, a second conductivity type semiconductor layer disposed on the first conductivity type semiconductor layer and electrically connected to the second electrode, and an active layer disposed between the first conductivity type semiconductor layer and the second conductivity type semiconductor layer;
the semiconductor layer has a mesa structure exposing a portion of the first conductivity type semiconductor layer; and
a heat transfer path between the first electrode and the mesa structure is longer than the maximum distance between the upper surface and the lower surface of the semiconductor layer beneath the first electrode.

3. The light emitting device of claim 2, wherein a difference between the heat transfer path between the first electrode and the mesa structure and the maximum distance between the upper surface and the lower surface of the semiconductor layer beneath the second electrode is within 10% of each other.

4. The light emitting device of claim 1, wherein, in the second opening, a distance between the upper surface of the semiconductor layer and an upper surface of the second electrode pad is shorter than the maximum distance between the upper surface and the lower surface of the semiconductor layer.

5. The light emitting device of claim 4, wherein, in the second opening, the distance between the upper surface of the semiconductor layer and the upper surface of the second electrode pad is longer than a minimum distance between the upper surface and the lower surface of the semiconductor layer.

6. The light emitting device of claim 2, wherein a peak wavelength (nm) of light generated in the active layer is between 0.085 and 0.133 times a distance (μm) from an upper surface of the second conductivity type semiconductor layer to the upper surface of the second electrode pad.

7. The light emitting device of claim 1, wherein the first insulation layer includes a first insulation sidewall surrounding the second opening and having a height that decreases toward the second opening.

8. The light emitting device of claim 7, wherein the first insulation sidewall forms an inclined surface having a constant slope.

9. The light emitting device of claim 7, wherein the first insulation sidewall includes a convex surface.

10. The light emitting device of claim 7, wherein the upper surface of the second electrode pad disposed over the first insulation sidewall forms an inclined pad surface.

11. The light emitting device of claim 10, wherein the inclined pad surface is convex.

12. The light emitting device of claim 1, wherein:
the second electrode includes a second electrode sidewall on a side surface thereof; and
the second electrode sidewall forms an inclined surface.

13. The light emitting device of claim 12, wherein the inclined surface is concave.

14. The light emitting device of claim 13, wherein an upper surface of the first insulation layer disposed over the second electrode sidewall includes a recess.

15. A light emitting device, comprising:
a substrate;
a semiconductor layer disposed on the substrate;
first and second electrodes disposed on the semiconductor layer;
a first insulation layer covering the first and second electrodes and disposed on the semiconductor layer;
a first electrode pad electrically connected to the first electrode through a first opening provided in the first insulation layer;
a second electrode pad electrically connected to the second electrode through a second opening provided in the first insulation layer; and
a second insulation layer disposed on an upper surface of the semiconductor layer beneath the second electrode and a contact electrode covering the second insulation layer, the second electrode being disposed on an upper surface of the contact electrode.

16. The light emitting device of claim 15, wherein:
the second insulation layer includes a second insulation sidewall on a side surface thereof; and
the second insulation sidewall forms an inclined surface.

17. The light emitting device of claim 16, wherein the inclined surface is concave.

18. The light emitting device of claim 16, wherein:
the contact electrode includes a contact sidewall on a side surface thereof; and
a slope of the contact sidewall is less than a slope of the second insulation sidewall.

19. The light emitting device of claim 15, wherein the first insulation layer includes an aluminum oxide layer and a main insulation layer disposed on the aluminum oxide layer.

20. A light emitting device, comprising:
a substrate;
a semiconductor layer disposed on the substrate;
first and second electrodes disposed on the semiconductor layer;
a first insulation layer covering the first and second electrodes and disposed on the semiconductor layer;
a first electrode pad electrically connected to the first electrode through a first opening provided in the first insulation layer; and
a second electrode pad electrically connected to the second electrode through a second opening provided in the first insulation layer,
wherein:
the first insulation layer includes a first insulation sidewall surrounding the second opening and having a height that decreases toward the second opening; and
the first insulation sidewall includes a convex surface.
